(19) United States
(12) Patent Application Publication
(10) Pub. No.: US 2024/0421558 A1
(43) Pub. Date: Dec. 19, 2024

(54) OPTOELECTRONIC DEVICE

(71) Applicant: ams-OSRAM International GmbH, Regensburg (DE)

(72) Inventors: Tansen VARGHESE, Regensburg (DE); Alvaro GOMEZ-IGLESIAS, Regensburg (DE); Martin HETZL, Painten (DE)

(73) Assignee: ams-OSRAM International GmbH, Regensburg (DE)

(21) Appl. No.: 18/699,604

(22) PCT Filed: Sep. 1, 2022
(86) PCT No.: PCT/EP2022/074318

§ 371 Date: Apr. 9, 2024

(30) Foreign Application Priority Data
Oct. 15, 2021 (DE) 102021126781.1

(51) Int. Cl. H01S 5/026; H01S 5/02315

(52) U.S. Cl. CPC H01S 5/0264; H01S 5/0261; H01S 5/02315

(57) ABSTRACT

An optoelectronic device is specified including emitters, each emitter configured to emit electromagnetic radiation, and an assigned receiver for each emitter, configured to receive at least part of the electromagnetic radiation emitted by the emitter, wherein the emitters are configured to be operated with an input voltage, each receiver is configured to provide at least part of an output voltage, each emitter is physically connected to the assigned receiver.

### CROSS-REFERENCE TO RELATED APPLICATIONS

The present application is a national stage entry from International Application No. PCT/EP2022/074318, filed on Sep. 1, 2022, published as International Publication No. WO 2023/061659 A1 on Apr. 20, 2023, and claims priority to German Patent Application No. 10 2021 126 781.1, filed Oct. 15, 2021, the disclosures of all of which are hereby incorporated by reference in their entireties.

### FIELD

An optoelectronic device is specified herein.

### BACKGROUND

A problem to be solved is to specify an optoelectronic device which can be designed to be particularly compact.

### SUMMARY

According to at least one aspect, the optoelectronic device comprises an emitter, in particular the optoelectronic device comprises a plurality of emitters. Each emitter is configured to emit electromagnetic radiation. Further, the emitters are adapted to be operated with an input voltage. For example, each emitter may be a device that generates electromagnetic radiation in the wavelength range between infrared radiation and ultraviolet radiation. In particular, each emitter may be configured to generate electromagnetic radiation in the wavelength range from at least 250 nm to at most 1600 nm during operation.

According to at least one aspect of the optoelectronic device, the optoelectronic device comprises a receiver, in particular a plurality of receivers. Each receiver is assigned to an emitter of the plurality of emitters and may be designated here and in the following as an “assigned receiver”. For example the number of emitters equals the number of receivers.

Each assigned receiver is configured to receive the electromagnetic radiation of the assigned emitter and to provide part of an output voltage of the optoelectronic device. In particular, the assigned receiver is configured to receive the electromagnetic radiation emitted by the emitter during operation and to convert it at least partially into electrical energy. In particular, the assigned receiver can be tuned to the emitter in such a way that the assigned receiver has a particularly high absorption for the electromagnetic radiation generated by the emitter.

According to at least one aspect of the optoelectronic device, each emitter is physically connected to the assigned receiver. That is to say that for example for each emitter there is exactly one assigned receiver and the emitter and the assigned receiver are physically connected to each other. For example, it is possible that the emitter and the assigned receiver are in direct physical contact with each other. Further, it is possible that at least one element, for example a layer, is arranged between the emitter and the assigned receiver. This layer mediates bonding between the emitter and the assigned receiver such that both elements of the optoelectronic device are physically connected to each other.

According to at least one aspect of the optoelectronic device, the optoelectronic device comprises
emitters, each emitter configured to emit electromagnetic radiation,
an assigned receiver for each emitter, configured to receive at least part of the electromagnetic radiation emitted by the emitter, wherein
the emitters are configured to be operated with an input voltage,
each receiver is configured to provide at least part of an output voltage,
each emitter is physically connected to the assigned receiver.

According to at least one aspect of the optoelectronic device, each emitter comprises at least one surface emitter. In the present context, a surface emitter is understood to mean a radiation-emitting component which emits the electromagnetic radiation generated during operation transversely, in particular perpendicularly, to a mounting surface on which the radiation-emitting component is mounted. In particular, the surface emitter may be a semiconductor device comprising an epitaxially grown semiconductor body. In particular, the direction in which the electromagnetic radiation is then emitted during operation may be parallel to a growth direction of the semiconductor body. For example, the semiconductor body may be based on semiconductor materials such as (Al) InGaN, In (Ga) AlP, InGa (As) P, InGa (Al) As, (Al) GaAs, and (In) GaAs.

The surface emitter may be, for example, a light-emitting diode, a laser diode, a superluminescent diode or a VCSEL. In this context, each emitter may comprise exactly one or a plurality of surface emitters, which may be connected to each other in series and/or in parallel.

According to at least one aspect of the optoelectronic device, each receiver comprises at least one photodiode. The photodiode may comprise a semiconductor body having at least one active or detecting region configured to absorb electromagnetic radiation generated by the at least one surface emitter during operation and convert it into electrical energy. The at least one photodiode may be formed, for example, in the same material system as the at least one surface emitter. In particular, the receiver may comprise a plurality of photodiodes that may be connected together in series or in parallel.

The optoelectronic device described herein is based on the following considerations, among others.

Many applications, such as in acoustics, beam steering technologies such as MEMS, actuators, detectors such as avalanche photodiodes, single photon avalanche diodes, or photomultipliers, require high voltage supplies with relatively low power consumption. Such applications may require voltages in excess of 50 V, 100 V, 500 V, 1000 V, 2000 V, 10000 V, and more, while maintaining a small device footprint in terms of size, weight, cost, and power consumption. These characteristics are especially important for mobile devices such as AR/VR glasses, wearable in-ear headsets, and automotive applications.

Another problem to be solved for high-voltage generators with small footprint is the connection of low-voltage and high-voltage paths, which should be galvanically separated to ensure the functional reliability and long-term stability of a device under changing environmental conditions such as temperature, humidity, dust.

The optoelectronic device described here can advantageously be used as an optical voltage converter. Further, with modifications of the optoelectronic device described herein, it is also possible to convert a high voltage on the side of the emitters to a low voltage on the side of the receivers. Furthermore, with modifications of the present device, it is possible to transform an AC voltage into a DC voltage and vice versa. Finally, the present device also makes it possible to transfer galvanically isolated power from the side of the emitters to the side of the receivers without changing the voltage. For example, the modifications could be changes in the circuitry and/or material system used in the device.

The optoelectronic device described here can thus form, for example, a transformer that can do without inductive elements, in particular without coils. On the one hand, this makes the installation space particularly small compared to conventional transformers, and on the other hand, no or only small magnetic fields are generated during the transformation. This also rules out any influence from external magnetic and/or electric fields. Thus, the optoelectronic device can be used in areas for which magnetic interference would be critical or which are subject to high external magnetic fields. At the same time, the optical power transmission in the optoelectronic device ensures galvanic isolation from the high-voltage side and the low-voltage side.

Another idea of the device described here is to combine semiconductor light emitters and receivers, i.e. photodiodes or photovoltaic cells, to achieve a conversion from low to high voltages. For this purpose on the low voltage side of the device, one or more emitters connected in parallel emit light. The wavelength of the emitted light can be between 250 nm and 1600 nm, depending on the semiconductor materials used, for example: (Al) InGaN, In (Ga) AlP, InGa (As) P, InGa (Al) As, (Al) GaAs, and (In) GaAs. Typical input voltages are 1 V, 3 V, 5 V, 8 V, 10 V or in between.

On the high voltage side, which is galvanically isolated from the low voltage side, series-connected receivers, e.g. photodiodes operating in photovoltaic mode, collect the emitted light. Depending on the material used, for example Si, InGaAs, GaAs, InGaN or perovskite, each photodiode generates a voltage in the order of 0.5-3 V and a current depending on the intensity of the incident light. By using a large number of photodiodes, all of which can be connected in series on a very small wafer scale, these individual voltages add up to a high total voltage that can exceed 10, 50, 100, 500, 1000, 10000 V.

Overall, the present device enables the transmission of energy and/or the conversion of voltage in a particularly compact component. The optoelectronic device is thereby insensitive to external influences such as temperature fluctuations or electromagnetic fields.

According to at least one aspect of the optoelectronic device, each emitter and the assigned receiver are monolithically integrated with each other. For example, each emitter comprises an epitaxially grown semiconductor body. In case the emitter and the assigned receiver are monolithically integrated, the receiver is epitaxially grown onto the semiconductor body of the emitter, or vice versa. Thereby it is possible that at least one further epitaxially grown insulating layer is arranged between the emitter and the assigned receiver. In this case the emitter and the assigned receiver are connected with each other during the epitaxial production process. For example, it is possible that the emitters are grown together in a wafer and the receivers are subsequently grown onto the emitters in the same wafer. This allows for a particularly cost-saving production of the optoelectronic semiconductor device.

According to at least one aspect of the optoelectronic device, each emitter and the assigned receiver are bonded to each other. In this case, the emitter and the receiver are not epitaxially grown onto one another but they are bonded to each other, for example by using a bonding layer which is arranged between each emitter and the assigned receiver or by means of direct bonding. Such a bonding layer can also act as an electrically insulating separation layer between the emitter and the assigned receiver. For such a device the material system of the assigned receiver can be chosen more independently from the material system of the emitter than is the case for the monolithic integration of emitter and assigned receiver.

According to one aspect of the optoelectronic device, each emitter comprises a carrier and the assigned receiver is arranged at a side of each emitter facing away from the carrier. For example, the carrier can be a growth substrate for the emitters. Further it is possible that the carrier is formed by a connection carrier, like a circuit board, via which the emitters can be electrically contacted. In case the carrier is a growth substrate, it is further possible that the carrier is electrically conductive at the side of the emitters. In this way it is possible that the emitters are, for example, connected in parallel via the carriers or via structures on the carrier. That is to say, the carrier can be a common carrier for two, more or all emitters of the optoelectronic device. Further it is possible that each emitter comprises its own carrier that is different from the carrier of the remaining emitters.

According to one aspect of the optoelectronic device, an electrically insulating separation layer is arranged between each emitter and the assigned receiver. In particular, in the case where the input voltage is lower than the output voltage, there can be a large potential difference between the receivers and the emitters. For example, the potential difference can be 1000 V or higher. For a potential difference of 1000 V and a thickness of the electrically insulating separation layer of 1 μm, the field strength of the electrical field is 1 GV/m.

According to one aspect of the optoelectronic device, the electrically insulating separation layer has a larger bandgap than adjacent layers which abut the electrically insulating separation layer. In this way, the electrically insulating separation layer can withstand the described high electrical field strengths. Further, such an electrically insulating separation layer not only prevents the carrier from crossing from the emitter to the receiver, but also the absorption of the electromagnetic radiation generated by the emitter is prevented. For example, the electrically insulating separation layer can be formed by AlₓGaAs with x≥0.9, GaAs, silicon dioxide, silicon nitride, in particular sputtered silicon nitride, and/or diamond or diamond-like carbon films. An electrically insulating separation layer formed with AlₓGaAs can be laterally oxidized or a compensating dopant such as Fe can be implanted and annealed between growing the emitter and the assigned receiver.

According to at least one aspect of the optoelectronic device, the device further comprises an assigned bypass diode for each receiver, wherein the assigned bypass diode is connected in antiparallel to the receiver. Such a bypass diode can, for example, be used to shunt a receiver which is not illuminated. In this way a receiver which is physically connected to an emitter which is not working or which is not operated is not destroyed by becoming reverse biased, but the current can flow through the bypass diode which is connected in antiparallel.

According to at least one aspect of the optoelectronic device, the bypass diode and the assigned receiver are physically connected to each other. Thereby it is, for example, possible that the bypass diode and the assigned receiver are monolithically integrated with each other or bonded to each other. Here, monolithically integrated again means that the bypass diode can be grown epitaxially onto the assigned receiver. For example, the optoelectronic device then comprises a plurality of components where each component comprises an emitter, an assigned receiver physically connected to the emitter, and an assigned bypass diode physically connected to the assigned receiver. For example, the assigned receiver is arranged on top of the emitter and the bypass diode is arranged on top of the assigned receiver, at a side of the receiver facing away from the emitter.

According to at least one aspect of the optoelectronic device, all emitters are configured to be operable independently from each other. That is to say, for example all emitters can be switched independently from each other so that each emitter can be operated or not. In this way it is, for example, possible to switch off defect emitters or to control the output voltage of the optoelectronic device.

According to one aspect of the optoelectronic device, all receivers are configured to be operable independently from each other. That is to say, each receiver can be switched independently to be operated or not to be operated. Thereby it is, for example, possible to switch pairs of emitters and assigned receivers on and off and thus to control the input voltage and the output voltage.

According to at least one aspect of the optoelectronic device, the assigned receiver is configured to be bypassed when the emitter is not operated. For example, each assigned receiver is assigned to a switch which bypasses the assigned receiver when the assigned receiver is not operated. Such a switch can, for example, comprise or consist of a transistor which is connected in parallel to the assigned receiver. Further, a bypass diode can be connected antiparallel to the receiver as a failsafe when the assigned receiver is not operated unintentionally, e.g. in case the emitter is not working.

According to at least one aspect of the optoelectronic device, the input voltage of the device is lower than the output voltage of the device and the assigned receivers of operated emitters are connected in series. That is to say, the assigned receivers are connected in series only for such emitters which are operated, for example by using a switch for each receiver which is connected in parallel to bypass the receiver in case an emitter is intentionally switched off.

In the following the optoelectronic device described herein is explained in more detail by means of exemplary embodiments and the associated figures.

### BRIEF DESCRIPTION OF THE DRAWINGS

With regard to the schematic drawings of FIGS. 1, 2, 3, 4, 5A, 5B, 6, 7A, 7B and 7C embodiments of optoelectronic devices described herein are explained in more detail.

### DETAILED DESCRIPTION

FIG. 1 shows, in a schematic sectional view, part of an optoelectronic device described herein.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

FIG. 1 shows one pair of an emitter 1 and an assigned receiver 3. For example, the emitter 1 is epitaxially grown on the carrier 4. In this case the carrier 4 can be a conducting, e.g. n-conducting, substrate. However, it is also possible that the growth substrate is removed from the emitter 1 and the carrier 4 is a substrate bonded to the emitter or a circuit board connected with the emitter 1.

The emitter 1 comprises an active zone 13 which is arranged between n-conducting and p-conducting semiconductor layers. On both sides of the active zone 13, mirrors 14, 15 are arranged. The first mirror 14 abuts a first contact 11 of the emitter 1 via which the emitter 1 is, for example, contacted from its n-side. The second mirror 15 is arranged at the e.g. p-side of the emitter 1 which is contacted via a second contact 12 which, for example, at least partly surrounds the second mirror 15. The first mirror and the second mirror for example each comprise a plurality of layers with alternating refraction indices. In this way both mirrors, for example, can be formed by electrically conductive distributed Bragg reflection mirrors.

At a side of the emitter 1 facing away from the carrier 4, the assigned receiver 3 is arranged. For example, the receiver 3 is epitaxially grown onto the emitter 1. In this case the receiver and the emitter 1 are monolithically integrated with each other. However, it is also possible that emitter 1 and receiver 3 are bonded to each other, for example by a high dielectric strength bonding material like silicon dioxide or silicon nitride. In each case an electrically insulating separation layer 5 is arranged between the emitter 1 and the receiver 3. Further, the emitter 1 and the assigned receiver 3 are physically connected to each other. Electrically isolating mirrors can be incorporated in this case of bonded emitter and receiver.

The receiver 3 comprises an active region 33 which is configured to receive a radiation 2 which is produced during operation by the emitter 1. The receiver 3 converts part of the radiation 2 into electrical energy. The receiver 3 comprises a first contact 31 and a second contact 32. In the shown embodiment the first contact 31 is for example n-conducting and the second contact 32 is p-conducting. The pair of emitter 1 and receiver 3 can be passivated by an electrically insulating cover layer 6 which, for example, covers at least parts of the side surfaces and the top surface of the arrangement of emitter 1 and assigned receiver 3.

In the embodiment of FIG. 1, the emitter 1 is for example a VCSEL and the receiver 3 is or comprises at least one photodiode.

The contacts 31 and 12 are, for example, formed after etching the semiconductor layers of the receiver and the emitter. For example, the semiconductor layers of the receiver 3 are etched to an n-contact layer and the n-contact 31 is formed. Subsequently the semiconductor layers of the emitter 1 are etched to a p-contact layer of the emitter 1 and the p-contact 12 is formed. Further, afterwards it is possible to etch the layers to the carrier 4 in order to form an n-contact of the emitter 1, for example contact 11.

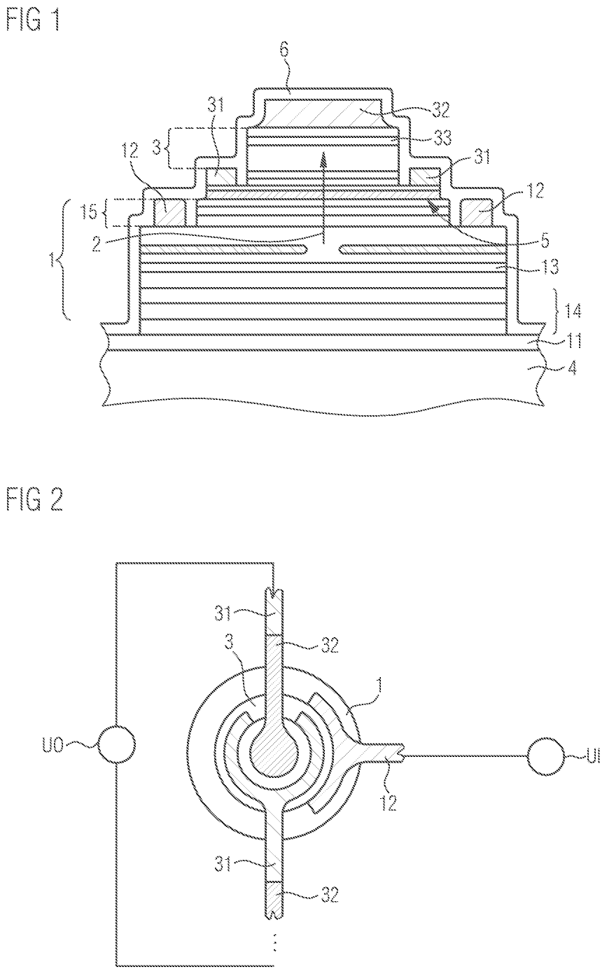

A here described optoelectronic device comprises a plurality of pairs of emitters 1 and receivers 3, as shown in FIG. 1. In these pairs the emitters 1 are, for example, connected in parallel with the chosen number of emitters which should be operated. The receivers 3 are then, for example, connected in series with each other. This is shown in the schematic top view of FIG. 2, which shows a pair of emitter 1 and assigned receiver 3 where the first contact 31 of the receiver 3 can be connected to the second contact 32 of an adjacent pair of an emitter 1 and an assigned receiver 3. The emitters are driven with the input voltage UI and the output voltage UO is obtained from the receivers 3.

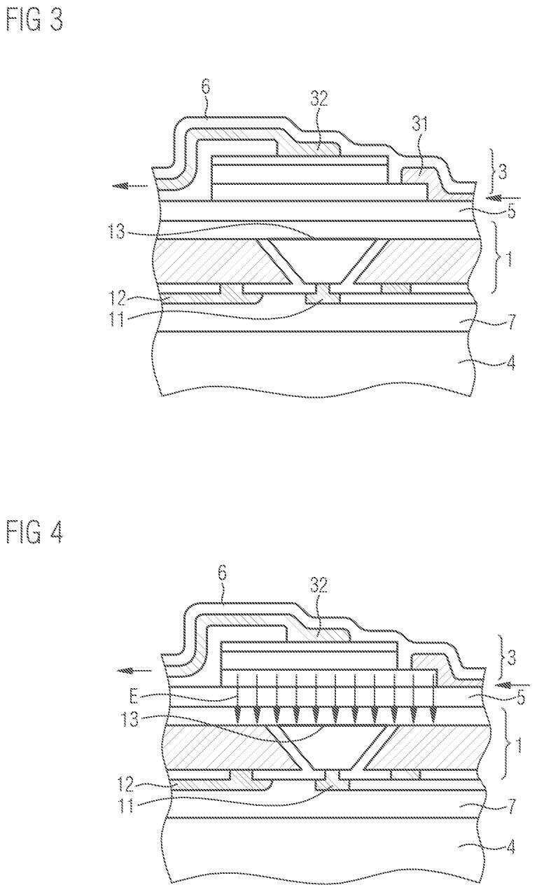

The schematic view of FIG. 3 shows a pair of an emitter 1 and an assigned receiver 3 for a further embodiment of a here described optoelectronic device. In this embodiment the contacts 11, 12 of the emitter 1 are both between the carrier 4 and the remaining layers of the emitter 1. With this a better electrical separation of the emitter and the receiver 3 is possible. For example, an electrically insulating base layer 7 is arranged between the carrier 4 and the emitter 1. In this electrically insulating base layer 7 the first contact 11 and the second contact 12 of the emitter 1 can be embedded.

In connection with the schematic view of FIG. 4, a problem of the embodiment of the optoelectronic device as shown in FIG. 3 is illustrated. In case the input voltage UI of the device is lower than the output voltage UO of the device, a large potential can be present at the receiver 3, while the emitter 1 has a low potential. From this a strong electric field E can arise which can lead to leakage of charge carriers like electrons.

Consequently the electrically insulating separation layer 5 proves to be advantageous for the separation between the emitter 1 and the assigned receiver 3. Further, the electrically insulating separation layer 5 should have a larger bandgap than the surrounding layers of the receiver 3 and the emitter 1 in order to be transparent for the electromagnetic radiation 2 which radiates from the emitter 1 through the electrically insulating separation layer 5 into the receiver 3 and in order to prevent charge carriers from migrating to the receiver 3 from the emitter 1. For example, the electrically insulating separation layer 5 can be formed by AlₓGaAs with x≥0.9, GaAs, silicon dioxide, silicon nitride, in particular sputtered silicon nitride and/or diamond or diamond-like carbon films.

A here described optoelectronic device has inter alia the advantage that the emitter 1 and the receiver 3 can be perfectly aligned to each other such that a maximum coupling of the electromagnetic radiation 2 from the emitter 1 into the receiver 3 is possible. Further, the emitter 1 and the receiver 3 can be designed together to share modes, i.e. standing electromagnetic waves, which optimizes the absorption of the electromagnetic radiation 2 in the receiver. Both emitter 1 and receiver 3 can be multi-junction and optionally multi-wavelength devices, which allows for higher voltages and/or higher currents.

In case the receiver 1 and the emitter 3 of each pair of emitters and assigned receivers are bonded to each other, the electrically insulating separation layer 5 can be used as a bonding layer and chosen in such a way that the layer has a high breakdown strength. Further, the semiconductor materials for forming the emitter 1 and the assigned receiver 3 can be more freely chosen in comparison to a monolithically integrated pair of emitter 1 and assigned receiver 3. However, the production costs for bonding emitters and receivers may be higher than for the monolithic approach where emitter and assigned receiver are epitaxially grown onto each other.

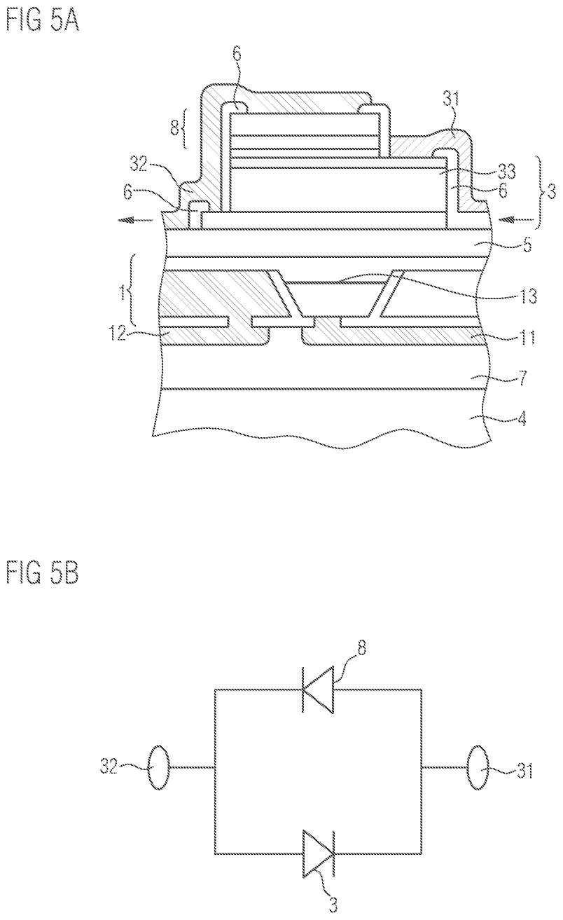

In connection with the schematic views of FIG. 5A and FIG. 5B, a further embodiment of a here described optoelectronic device is discussed. In comparison to the embodiment of FIG. 3, the pair of emitter 1 and receiver 3 further comprises a bypass diode 8. The bypass diode 8 can, for example, be monolithically integrated with the receiver 3 or it is bonded to the receiver 3. The bypass diode 8 comprises a pn-junction connected antiparallel to the pn-junction of the receiver 3, also see FIG. 5B. The bypass diode 8 can shunt the receiver 3 in case the receiver 3 is not illuminated by the emitter 1. For example, in this way a receiver 3 coupled to an emitter 1 which is not working or which is not operated is not destroyed by becoming reverse biased.

A connection between the bypass diode 8 and the receiver 3 can be, for example, established by contacts 31 and 32 of the receiver as shown in FIGS. 5A and 5B.

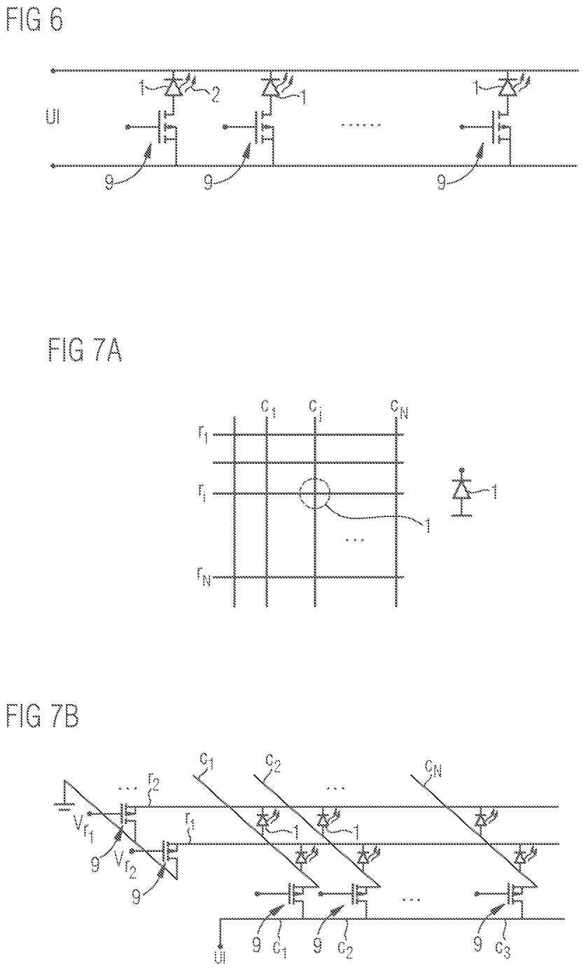

In connection with FIG. 6 an embodiment of a here described optoelectronic device is explained in which all emitters 1 are configured to be operable independently from each other. In this embodiment the emitters 1 are connected in parallel. The current injected in each emitter 1 is controlled by a switch 9, wherein each emitter is assigned its own switch 9. For example, each switch 9 comprises a p-channel MOSFET and the p-channel MOSFETS are controlled by means of the gate voltage. The emitters connected in parallel are operated with the input voltage UI of the device.

Such a backing circuitry for the emitters 1 can be integrated at wafer level. Therefore, additional interposers or active CMOS wafers are possible. The number of emitters 1 that are turned on can be changed with a suitable design of the emitter connection circuitry, for example using the switches 9 as shown in the embodiment of FIG. 6. A corresponding circuit for the receivers 3, which then are connected in series, can be used to remove the receivers 3 which are not illuminated by assigned emitters 1, for example when emitters 1 are switched off. Both emitters 1 and receivers 3 can then be operated similar to the pixels of an active matrix display.

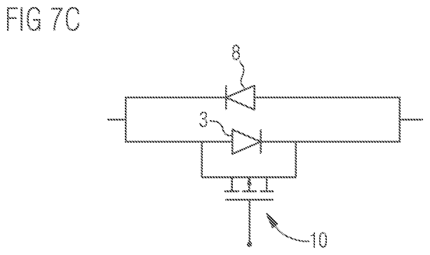

In connection with the schematic views of FIGS. 7A to 7C, a further embodiment of a here described device is explained. In this embodiment there is a two-dimensional arrangement of emitters 1 and two separate metallization grids separated into rows r and columns c allow to contact individual or groups of emitters 1 by applying voltages to the appropriate columns c and rows r. This is shown in more detail in the three-dimensional view of FIG. 7B, from which it becomes clear that a switch 9, for example a transistor, switches each individual row or column.

Due to the one-to-one assignment of emitters 1 and receivers 3, if an emitter 1 is switched off the corresponding receiver 3 must be bypassed to avoid voltage loss. This can, for example, be done as shown in the schematic view of FIG. 7C, where a switch 10 for a receiver 3, for example a transistor, is connected in parallel to bypass the receiver 3 in case an emitter 1 is intentionally switched off. As a failsafe for the case when the emitter 1 is unintentionally switched off a bypass diode 8 as, for example, explained in connection with FIGS. 5A and 5B may be connected antiparallel to the receiver 3.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1. An optoelectronic device comprising:
emitters, each emitter configured to emit electromagnetic radiation, and
an assigned receiver for each emitter, configured to receive at least part of the electromagnetic radiation emitted by the emitter, wherein
the emitters are configured to be operated with an input voltage,
each receiver is configured to provide at least part of an output voltage,
each emitter is physically connected to the assigned receiver,
all emitters are configured to be operable independently from each other, and
all receivers are configured to be operable independently from each other.

2. The optoelectronic device according to claim 1, wherein each emitter comprises a surface emitter and each receiver comprises a photodiode.

3. The optoelectronic device according to claim 1, wherein each emitter and the assigned receiver are monolithically integrated with each other.

4. The optoelectronic device according to claim 1, wherein each emitter and the assigned receiver are bonded to each other.

5. The optoelectronic device according to claim 1, wherein each emitter comprises a carrier and the assigned receiver is arranged at a side of each emitter facing away from the carrier.

6. The optoelectronic device according to claim 1, wherein an electrically insulating separation layer is arranged between each emitter and the assigned receiver.

7. The optoelectronic device according to claim 6, wherein the electrically insulating separation layer has a larger bandgap than adjacent layers.

8. The optoelectronic device according to claim 1, further comprising an assigned bypass diode for each receiver, wherein the assigned bypass diode is connected in antiparallel to the receiver.

9. The optoelectronic device according to claim 8, wherein the bypass diode and the assigned receiver are physically connected to each other.

10. The optoelectronic device according to claim 9, wherein the bypass diode and the assigned receiver are monolithically integrated with each other or bonded to each other.

11. The optoelectronic device according to claim 1, wherein the assigned receiver is configured to be bypassed when the emitter is not operated.

12. The optoelectronic device according to claim 1, wherein the input voltage is lower than the output voltage and the assigned receivers of operated emitters are connected in series.

13. The optoelectronic device according to claim 1, wherein all receivers are configured to be operable independently from all emitters.
